(19) United States
(12) Patent Application Publication
(10) Pub. No.: US 2026/0134169 A1
(43) Pub. Date: May 14, 2026

(54) METHOD OF DESIGNING PLANAR ELECTROMAGNETIC COILS USING EXPLICITLY PLANAR COIL PARAMETERIZATIONS

(71) Applicants: David Gates, Princeton, NJ (US); Thomas Kruger, Princeton, NJ (US)

(72) Inventors: David Gates, Princeton, NJ (US); Thomas Kruger, Princeton, NJ (US)

(73) Assignee: Thea Energy, Inc., Branchburg, NJ (US)

(21) Appl. No.: 19/445,269

(22) Filed: Jan. 9, 2026

Related U.S. Application Data
(63) Continuation of application No. PCT/US24/39098, filed on Jul. 23, 2024.
(60) Provisional application No. 63/528,446, filed on Jul. 24, 2023.

(51) Int. Cl. G06F 30/20

(52) U.S. Cl. CPC G06F 30/20

(57) ABSTRACT

The present disclosure is directed to a method of generating a set of final free parameters which describe a design of one or more planar electromagnetic coils, such as for use in a stellarator. In some embodiments, the computing of the set of final free parameters describing the one or more planar coils includes a parametrization which describes one or more planar coils.

### CROSS REFERENCE TO RELATED APPLICATIONS

The present disclosure is a continuation of International Application No. PCT/US24/39098 filed on Jul. 23, 2024, which application claims the benefit of the filing date of U.S. Patent Application No. 63/528,446 filed on Jul. 24, 2023, the disclosures of which are hereby incorporated by reference herein in their entireties.

### FIELD OF THE DISCLOSURE

The present disclosure is directed to methods of generating a set of free parameters describing one or more planar coils for use in a stellarator.

### BACKGROUND OF THE DISCLOSURE

Fusion is a process which can be harnessed to release the nuclear energy in abundant fuels, without emissions of greenhouse gases and with significantly lower and shorter-lived radioactive waste than conventional fission nuclear reactors. Fusion fuels fuse only at extremely high temperature, at which all materials are in the plasma state.

Magnetic fusion devices aim to confine a fusing plasma using magnetic fields. The two leading magnetic fusion approaches are the tokamak and the stellarator, both of which utilize a magnetic field which has the topology of a torus.

Stellarators have the advantage over tokamaks of operating in steady state and requiring no additional electrical current to be driven within the plasma itself. Prior stellarator designs have included non-planar electromagnetic coils which have a complex, 3D curvature. These electromagnetic coils are difficult to design, fabricate, integrate, and maintain. Some stellarator designs include electromagnetic coils which link other electromagnetic coils, akin to the links of a chain. These electromagnetic coils cannot be fabricated separately and then assembled; they must be fabricated together, which further increases the difficulty of their fabrication, integration, and maintenance.

One example of a stellarator employing complex electromagnetic coils is the Large Helical Device (LHD) experiment operated by the Japanese National Institute for Fusion Science (Yoshimura, Y., et al. 2005. Journal of Physics: Conference Series 25 (1): 189). These electromagnetic coils are helical coils, which are non-planar and interlock the plasma and the other helical coils. These electromagnetic coils must be wound with electrical wire on-site. Stellarators employing such electromagnetic coils are termed Torsatrons or Heliotrons.

The HSX stellarator (Anderson, F. et al. Fusion Technology 27, no. 3T (Apr. 1, 1995): 273-77. https://doi.org/10.13182/FST95-A11947086) and W7-X stellarator (Beidler, Craig, et al. Fusion Technology 17, no. 1 (Jan. 1, 1990): 148-68. https://doi.org/10.13182/FST90-A29178) comprise planar coils (130). The planar coils of W7-X and HSX do not carry current during the highest-performance plasma confinement configurations. Rather, they exist to perform experiments at off-nominal conditions. Consequently, in HSX they are called “auxiliary coils.” Notably, the planar coils (130) of both the HSX and W7-X stellarators were not designed using a numerical optimization. Rather, they were designed by placing planar coils around a plasma axis and a modular coil system.

The NCSX stellarator design (Williamson, D., et al. Fusion Engineering and Design, Proceedings of the 23rd Symposium of Fusion Technology, 75-79 (Nov. 1, 2005): 71-74. https://doi.org/10.1016/j.fusengdes.2005.06.254) comprises non-planar encircling coils and Toroidal Field (TF) coils, where the toroidal field coils are planar and arranged in a rotationally symmetric configuration to produce a toroidally-directed magnetic field. Like the coils of the HSX and W7-X stellarators, the TF coils of the NCSX stellarator were not designed using numerical optimization. Instead, they were designed by placing identical planar coils rotationally symmetrically around a cylindrical axis.

The ZCS stellarator design (Yu, Guodong, et al. Physics of Plasmas 28, no. 9 (Sep. 2, 2021): 092501. https://doi.org/10.1063/5.0057834) and a stellarator design published by Moroz in 1995 (Moroz, Paul E. Physics of Plasmas 2, no. 11 (November 1995): 4269-84. https://doi.org/10.1063/1.871052) comprise planar coils which were designed using numerical optimization. In these design methods, the authors used a parametrization of the planar coils which describes only planar coils, but these coils were limited in shape to exclusively ellipses, circles, D-shapes, and rectangles. ZCS Iso allowed the planar coils to be linked with one another like the links of a chain, making the systems more complex as described above.

To-date, stellarators include only planar coils for which either (i) the coils were not designed using numerical optimization (e.g., the planar coils of W7-X, HSX, and NCSX) or; (ii) the coils are non-planar and were designed using numerical optimization (e.g., the non-planar coils of W7-X, HSX, and NCSX); and/or (iii) the coils are planar and were designed using a numerical optimization technique utilizing a parametrization which can only describe a limited subset of coil shapes (e.g., the ZCS stellarator; Moroz, 1995).

### BRIEF SUMMARY OF THE DISCLOSURE

The confinement of a plasma in a stellarator requires the creation of a three-dimensional magnetic field using one or more electromagnetic coils. The magnetic field produced by an electromagnetic coil depends on its shape, location, rotation, and the amount of electrical current that flows through that coil. The present disclosure is directed to systems and methods for computing a set of free parameters describing one or more planar coils, such as one or more planar coils for confining a plasma within a stellarator or within one or more components of a stellarator. The set of free parameters describing the one or more planar coils depends upon a parameterization which is used to define and perturb, i.e., optimize, the geometric shape of one or more planar coils. In some embodiments, any free parameters that are included in the parameterization of the coil will be perturbed throughout an optimization to change the geometric shape of the coils. In some embodiments, the set of free parameters may also include the coil currents, coil translations in space, and coil rotations in space.

Conventionally, planar coils have been designed using numerical optimization where a parametrization was utilized which could only describe planar coils (see Yu, Guodong, et al. Physics of Plasmas 28, no. 9 (Sep. 2, 2021): 092501. https://doi.org/10.1063/5.0057834). These design methods are limited, however, in that they can only describe a limited set of planar coil shapes. The parametrization used by ZCS can only describe ellipses, while that used by Moroz can only describe a given rotation and translation of a pre-specified planar shape, such as circles, D-shapes, or rectangles (see Moroz, Paul E. Physics of Plasmas 2, no. 11 (November 1995): 4269-84. https://doi.org/10.1063/1.871052). It is believed that this limited parametrization caused numerical optimizers to fail to find a global optimum of the objective function. This resulted in coils which were inferior with respect to magnetic field accuracy, coil feasibility, or both.

In the methods of the present disclosure, substantially planar coils are designed using a numerical optimization utilizing a parametrization which can describe arbitrarily complex coil shapes. This extended parametrization is believed to permit the numerical optimizer to find a global optimum of the objective function despite the non-convexity of that function.

A first aspect of the present disclosure is a method of generating a set of free parameters which describe a design of one or more electromagnetic coils that are planar, comprising: (i) obtaining a set of initial free parameters, where the set of initial free parameters describe one or more initial planar coils; (ii) obtaining a total objective function, wherein the total objective function is derived from at least one penalty function; and (iii) performing a numerical optimization is based on (a) the obtained set of initial free parameters, (b) the obtained total objective function; and (c) a predetermined numerical optimization algorithm. In some embodiments, the parametrization used is able to describe a variety of planar coil shapes. For instance, the parameterization may rely upon an arbitrarily large set of basic functions like sines and cosines in a Fourier series. Theoretically any planar coil geometry may be described using some parameterizations.

In some embodiments, the total objective function is derived from at least two penalty functions.

In some embodiments, each of the at least two penalty functions corresponding to a different quantity to penalize. In some embodiments, a second of the at least two penalty functions correspond to a magnetic field error quantity to penalize. In some embodiments, the different quantities to penalize are selected from the group consisting of magnetic field error, coil-to-plasma distance, coil curvature, coil convexity, individual coil length, total coil length, total conductor length, and coil-to-coil spacing.

In some embodiments, a set of initial free parameters is derived by: (i) obtaining an initial planar coil shape; (ii) choosing a parametrization which can describe a wide range of planar coil shapes; and (iii) calculating the initial free parameters in the parameterization that approximate the initial coil shape. In some embodiments, the parameterization chosen for the numerical optimization comprises two components, namely a parametrization for a planar coil which is represented as a closed curve in a 2D plane, and a parametrization for placing that 2D plane and therefore the coil into 3D space. In some embodiments, the parametrization for placing a 2D plane into 3D space consists of a rotation matrix and a translation vector. In some embodiments, the parametrization for placing a 2D plane into a 3D space consists of a full 4×4 affine transformation matrix. In some embodiments, the initial planar design describes a set of rotationally symmetric, circular coils. In some embodiments, set of initial planar design describes a set of coils which are placed and rotated rotationally symmetrically around a common axis. In some embodiments, the initial planar coil design includes between about 2 and about 100 coils. In some embodiments, the one or more coils of the initial planar coil design have an initial radius ranging from between about 1 cm to about 2000 cm.

In some embodiments, the predetermined numerical optimization is selected from a Quasi-Newton algorithm, a Levenberg-Marquardt algorithm, an Interior Point method, an Ellipsoid method, a Broyden-Fletcher-Goldfarb-Shanno algorithm, a Conjugate Gradient method, and a Gradient Descent algorithm. In some embodiments, the predetermined numerical optimization is a variation of one of these algorithms, such as L-BFGS-B, which is a limited-memory version of the Broyden-Fletcher-Goldfarb-Shanno algorithm, with bounds on the free parameters.

A second aspect of the present disclosure is a stellarator comprising: (a) a field-shaping coil system including one or more field shaping units which define a void adapted to confine a plasma, wherein each field shaping unit comprises: (i) one or more structural mounting elements; and (ii) one or more planar shaping coils disposed on a surface of the one or more structural mounting elements, wherein the one or more planar shaping coils do not interlock with each other, and where each of the one or more shaping coils do not individually encircle the plasma; and (b) a plurality of planar encircling coils which encircle and interlock the field-shaping coil system, and wherein each planar encircling coil of the plurality of planar encircling coils do not interlock with each other; wherein the plurality of planar encircling coils are described by a set of free parameters, wherein the set of free parameters are generated by (i) obtaining a set of initial free parameters, where the set of initial free parameters describe one or more initial planar coils; and (ii) obtaining a total objective function, wherein the total objective function is derived from at least one penalty function; and (iii) performing a numerical optimization is based on (a) the obtained set of initial free parameters, (b) the obtained total objective function; and (c) a predetermined numerical optimization algorithm. The parametrization used is able to describe a wide variety of planar coil shapes.

In some embodiments, the stellarator includes between about 3 and about 100 planar encircling coils. In some embodiments, the stellarator comprises at least four planar encircling coils. In some embodiments, the plurality of planar encircling coils is comprised of one or more superconducting materials. In some embodiments, the plurality of planar encircling coils does not interlock with each other. In some embodiments, the stellarator comprises at least 4 field shaping units. In some embodiments, wherein the surface of the one or more structural mounting elements faces the void. In some embodiments, each of the one or more field shaping units comprises one structural mounting element. In some embodiments, the one structural mounting element is wedge shaped. In some embodiments, each of the one or more field shaping units comprises two or more structural mounting elements. In some embodiments, the one or more planar shaping coils do not interlock with each other. In some embodiments, a shape of each planar shaping coil of the one or more planar shaping coils is substantially rectangular, substantially rectangular with rounded corners, or substantially circular. In some embodiments, each of the one or more field shaping units comprises between about 5 and about 100 shaping coils. In some embodiments, each of the one or more field shaping units comprises between about 5 and about 50 shaping coils. In some embodiments, the one or more shaping coils are comprised of a superconducting material. In some embodiments, the stellarator further comprises one or more controllers. In some embodiments, the stellarator further comprises one or more control coils and/or one or more saddle coils. In some embodiments, the one or more control coils and/or the one or more saddles coils are communicatively coupled to a controller. In some embodiments, each of the one or more shaping coils do not individually encircle the plasma.

A third aspect of the present disclosure is a stellarator comprising: (a) a field-shaping coil system including one or more field shaping units which define a void adapted to confine a plasma, wherein each field shaping unit comprises: (i) one or more structural mounting elements; and (ii) one or more shaping coils disposed on a surface of the one or more structural mounting elements; and (b) a plurality of encircling coils which encircle the plasma and the field-shaping coil system; wherein the one or more shaping coils and the plurality of encircling coils are comprised of one or more superconducting materials; and wherein each encircling coil of the plurality of encircling coils do not interlock with each other; wherein the plurality of planar encircling coils are described by a set of free parameters, wherein the set of free parameters are generated by (i) obtaining a set of initial free parameters, where the set of initial free parameters describe one or more initial planar coils; (ii) obtaining a total objective function, wherein the total objective function is derived from at least one penalty function; (iii) performing a numerical optimization is based on (a) the obtained set of initial free parameters, (b) the obtained total objective function; and (c) a predetermined numerical optimization algorithm. In some embodiments, the parametrization used is able to describe a wide variety of planar coil shapes.

In some embodiments, a shape of each of the one or more shaping coils is substantially rectangular, substantially rectangular with rounded corners, or substantially circular. In some embodiments, each of the one or more field shaping units comprises between about 5 and about 100 shaping coils. In some embodiments, each of the one or more field shaping units comprises between about 5 and about 50 shaping coils. In some embodiments, the one or more planar shaping coils do not interlock with each other. In some embodiments, each of the one or more field shaping units comprises one structural mounting element. In some embodiments, the one structural mounting element is wedge shaped. In some embodiments, each of the one or more field shaping units comprises two or more structural mounting elements. In some embodiments, each encircling coil of the plurality of encircling coils encircle the plasma confined within the void. In some embodiments, the stellarator includes between about 3 and about 100 encircling coils. In some embodiments, the stellarator comprises at least four encircling coils. In some embodiments, the plurality of encircling coils is comprised of one or more superconducting materials. In some embodiments, the planar encircling coils do not interlock with each other.

A fourth aspect of the present disclosure is a stellarator comprising: (a) a void adapted to confine a plasma having a plasma axis; (b) a plurality of planar shaping coils, wherein an array comprising the plurality of planar shaping coils encircles the plasma axis, but where any individual planar shaping coil of the plurality of planar shaping coils does not encircle the plasma axis; and (c) a plurality of planar encircling coils, wherein each individual planar encircling coil of the plurality of encircling coils encircles the plasma axis; and wherein each planar encircling coil of the plurality of planar encircling coils do not interlock with each other; wherein the plurality of planar encircling coils are described by a set of free parameters, wherein the set of free parameters are generated by (i) obtaining a set of initial free parameters, where the set of initial free parameters describe one or more initial planar coils; (ii) obtaining a total objective function, wherein the total objective function is derived from at least one penalty function; (iii) performing a numerical optimization is based on (a) the obtained set of initial free parameters, (b) the obtained total objective function; and (c) a predetermined numerical optimization algorithm. The parametrization used is able to describe a wide variety of planar coil shapes. In some embodiments, the plurality of planar shaping coils does not interlock one another. In some embodiments, the plurality of planar shaping coils does not interlock any one of the plurality of encircling coils. In some embodiments, plurality of planar encircling coils does not interlock one another. In some embodiments, the plurality of planar encircling coils does not interlock any one of the plurality of planar shaping coils. In some embodiments, the plurality of shaping coils is comprised of one or more superconducting materials. In some embodiments, the plurality of encircling coils is comprised of one or more superconducting materials. In some embodiments, the plurality of encircling coils and the plurality of planar shaping coils are both comprised of one or more superconducting materials. In some embodiments, a shape of each planar shaping coil of the one or more planar shaping coils is substantially rectangular, substantially rectangular with rounded corners, or substantially circular. In some embodiments, the stellarator comprises between about 10 and about 10,000 shaping coils. In some embodiments, the stellarator comprises between about 100 and about 2,000 shaping coils. In some embodiments, the stellarator includes between about 3 and about 100 planar encircling coils. In some embodiments, the stellarator comprises at least four planar encircling coils.

A fifth aspect of the present disclosure is stellarator comprising: (a) a void adapted to confine a plasma, wherein the void comprises at least two faces; (b) at least two planar shaping coils, wherein a first of the at least two planar shaping coils is proximal to a first of the at least two faces but does not encircle the void, and wherein a second of the at least two planar shaping coils is proximal to a second of the at least two faces but does not encircle the void; and (c) a plurality of planar encircling coils, wherein each individual planar encircling coil of the plurality of encircling coils encircles the plasma axis; wherein the plurality of planar encircling coils are described by a set of initial free parameters, wherein the plurality of planar encircling coils are described by a set of free parameters, wherein the set of free parameters are generated by (i) obtaining a set of initial free parameters, where the set of initial free parameters describe one or more initial planar coils; (ii) obtaining a total objective function, wherein the total objective function is derived from at least one penalty function; (iii) performing a numerical optimization is based on (a) the obtained set of initial free parameters, (b) the obtained total objective function; and (c) a predetermined numerical optimization algorithm. In some embodiments, the parametrization used is able to describe a wide variety of planar coil shapes.

In some embodiments, the at least two faces are on opposite sides of the confined plasma. In some embodiments, the at least two planar shaping coils do not interlock one another. In some embodiments, the at least two planar shaping coils do not interlock any one of the plurality of encircling coils. In some embodiments, plurality of planar encircling coils does not interlock one another. In some embodiments, the plurality of planar encircling coils does not interlock any one of the at least two planar shaping coils. In some embodiments, the at least two planar shaping coils are comprised of one or more superconducting materials. In some embodiments, the plurality of encircling coils is comprised of one or more superconducting materials. In some embodiments, the plurality of encircling coils and the at least two planar shaping coils are both comprised of one or more superconducting materials.

A sixth aspect of the present disclosure is a stellarator comprising: (a) a plurality of structural supports; (b) one or more field shaping units operably connected to the plurality of structural supports, each field shaping unit comprising one or more planar, surface-mounted shaping coils; and (c) a plurality of planar encircling coils; wherein the plurality of structural supports, the one or more field shaping units, and the plurality of encircling coils collectively define a void adapted for confining plasma therein; wherein the plurality of planar encircling coils are described by a set of free parameters, wherein the set of free parameters are generated by (i) obtaining a set of initial free parameters, where the set of initial free parameters describe one or more initial planar coils; (ii) obtaining a total objective function, wherein the total objective function is derived from at least one penalty function; (iii) performing a numerical optimization is based on (a) the obtained set of initial free parameters, (b) the obtained total objective function; and (c) a predetermined numerical optimization algorithm. The parametrization used is able to describe a wide variety of planar coil shapes.

A seventh aspect of the present disclosure is a method of designing a stellarator comprising: (a) obtaining a field-shaping coil system including one or more field shaping units which define a void adapted to magnetically confine a plasma, wherein each field shaping unit comprises: (i) one or more structural mounting elements; and (ii) one or more planar shaping coils disposed on a surface of the one or more structural mounting elements, wherein the one or more planar shaping coils do not interlock with each other, and where each of the one or more shaping coils do not individually encircle the plasma; and (b) obtaining a plurality of planar encircling coils which encircle the field-shaping coil system, and wherein the plurality of planar encircling coils are described by a set of free parameters, wherein the set of free parameters are generated by (i) obtaining a set of initial free parameters, where the set of initial free parameters describe one or more initial planar coils; (ii) obtaining a total objective function, wherein the total objective function is derived from at least one penalty function; (iii) performing a numerical optimization is based on (a) the obtained set of initial free parameters, (b) the obtained total objective function; and (c) a predetermined numerical optimization algorithm. The parametrization used is able to describe a wide variety of planar coil shapes.

In some embodiments, the total objective function is derived from at least three penalty functions.

In some embodiments, each penalty function each corresponds to a different quantity to penalize. In some embodiments, a second of the at least three penalty functions correspond to a magnetic field error quantity to penalize. In some embodiments, the different quantities to penalize are selected from the group consisting of magnetic field error, coil-to-plasma distance, coil curvature, coil convexity, individual coil length, total coil length, total conductor length, and coil-to-coil spacing.

In some embodiments, the set of initial free parameters are derived by performing a preliminary planar numerical optimization based on a set initial free parameters and a total objective function for the preliminary planar numerical optimization. In some embodiments, the total objective function for the preliminary planar numerical optimization is derived from one or more penalty functions for the preliminary planar numerical optimization.

In some embodiments, the set of initial free parameters derived by: (i) obtaining an initial planar coil design; and (ii) choosing a parametrization which can only describe planar coils; and (iii) parametrizing the initial planar coil design with the chosen parametrization. In some embodiments, the parameterization chosen for the numerical optimization is comprises two components: a parametrization for a planar coil which is represented as a closed curve in a 2D plane, and a parametrization for placing that 2D plane and therefore the coil into 3D space In some embodiments, the parametrization for putting a 2D plane into 3D space consists of a rotation matrix and a translation vector. In some embodiments, the parametrization for putting a 2D plane into 3D space consists of a full 4×4 affine transformation matrix. In some embodiments, the initial planar design describes a set of rotationally symmetric, circular coils. In some embodiments, set of initial planar design describes a set of coils which are placed and rotated rotationally symmetrically around a common axis. In some embodiments, the initial planar coil design includes between about 2 and about 100 coils. In some embodiments, the one or more coils of the initial planar coil design have an initial radius ranging from between about 1 cm to about 2000 cm.

In some embodiments, the predetermined numerical optimization is selected from a Quasi-Newton algorithm, a Levenberg-Marquardt algorithm, an Interior Point method, an Ellipsoid method, a Broyden-Fletcher-Goldfarb-Shanno algorithm, a Conjugate Gradient method, and a Gradient Descent algorithm. In some embodiments, the numerical optimization is a variation of one of these algorithms, such as L-BFGS-B, which is a limited-memory version of the Broyden-Fletcher-Goldfarb-Shanno algorithm, with bounds on the free parameters.

A ninth aspect of the present disclosure is a stellarator comprising: (a) a field-shaping coil system including one or more field shaping units which define a void adapted to confine a plasma, wherein each field shaping unit comprises: (i) one or more structural mounting elements; and (ii) one or more planar shaping coils disposed on a surface of the one or more structural mounting elements, wherein the one or more planar shaping coils do not interlock with each other, and where each of the one or more shaping coils do not individually encircle the plasma; and (b) a plurality of planar encircling coils which encircle and interlock the field-shaping coil system, and wherein each planar encircling coil of the plurality of planar encircling coils do not interlock with each other; wherein the plurality of planar encircling coils are described by a set of free parameters, wherein the set of free parameters are generated by (i) obtaining a set of initial free parameters, where the set of initial free parameters describe one or more initial planar coils; (ii) obtaining a total objective function, wherein the total objective function is derived from at least one penalty function; (iii) performing a numerical optimization is based on (a) the obtained set of initial free parameters, (b) the obtained total objective function; and (c) a predetermined numerical optimization algorithm. The parametrization used is able to describe a wide variety of planar coil shapes.

A tenth aspect of the present disclosure is a method of generating a set of initial free parameters which describe a design of one or more electromagnetic coils that are planar, comprising: obtaining a field-shaping coil system comprising a plurality of planar shaping coils, wherein the field-shaping coil system is adapted to magnetically confine a plasma; generating the set of initial free parameters which describe the design of the one or more electromagnetic coils that are planar, where the one or more electromagnetic coils that are planar encircle and interlock the field-shaping coil system, wherein the set of initial free parameters are generated by: obtaining a set of preliminary free parameters, where the set of preliminary free parameters describe one or more planar coils; obtaining a total objective function, wherein the total objective function is derived from at least one penalty functions, wherein one of the at least one penalty functions is derived from one or more quantities to penalize, wherein the one or more quantities to penalize for the first of the at least one penalty functions are selected from the group consisting of a required current in the plurality of shaping coils, a required conductor length of the plurality of shaping coils, and a maximum magnetic field of the plurality of shaping coils; wherein the plurality of shaping coils are described by a set of free parameters, wherein the set of free parameters are generated by (i) obtaining a set of initial free parameters, where the set of initial free parameters describe one or more initial planar coils; (ii) obtaining a total objective function, wherein the total objective function is derived from at least one penalty function; (iii) performing a numerical optimization is based on (a) the obtained set of initial free parameters, (b) the obtained total objective function; and (c) a predetermined numerical optimization algorithm. In some embodiments, the parametrization used is able to describe a wide variety of planar coil shapes

In some embodiments, each shaping coil of the plurality of shaping coils is planar. In some embodiments, the field-shaping coil system comprises one or more field shaping units which define a void adapted to confine the plasma, wherein each field shaping unit comprises: (i) one or more structural mounting elements; and (ii) the plurality of shaping coils disposed on a surface of the one or more structural mounting elements, wherein the plurality of shaping coils do not interlock with each other, and where each shaping coil of the plurality of shaping coils do not individually encircle the plasma. In some embodiments, each of the one or more field shaping units comprises between about 5 and about 100 shaping coils. In some embodiments, wherein the plurality of shaping coils is comprised of a superconducting material.

### BRIEF DESCRIPTION OF THE FIGURES

For a general understanding of the features of the disclosure, reference is made to the drawings. In the drawings, like reference numerals have been used throughout to identify identical elements.

FIG. 1 depicts the Wendelstein 7-X stellarator with a plasma and three sets of electromagnetic coils.

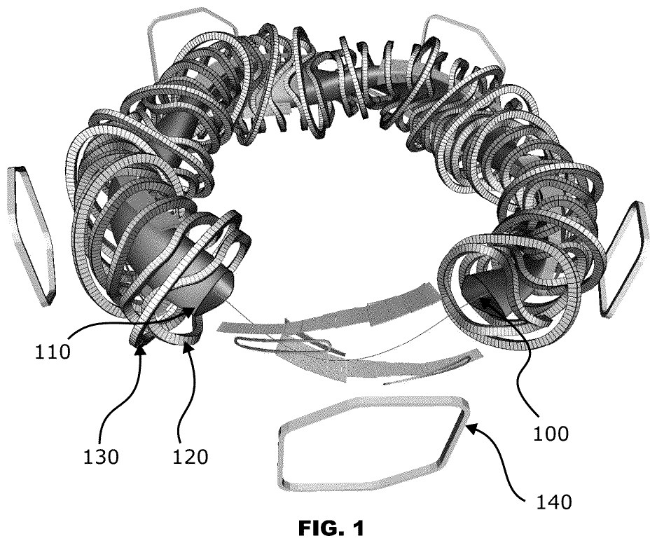

FIG. 2 depicts a stellarator design with a plasma and two sets of electromagnetic coils.

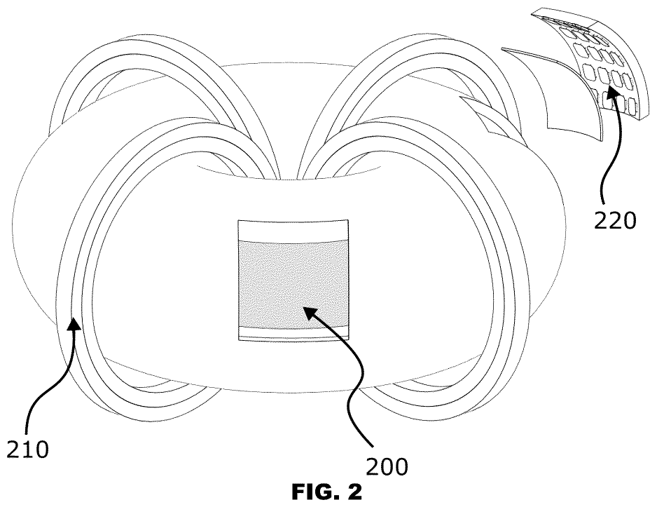

FIG. 3 provides a flowchart schematically representing the steps for performing one or more numerical optimizations in accordance with one embodiment with the present disclosure.

FIG. 4 depicts a system for performing a numerical optimization in accordance with one embodiment of the present disclosure.

FIG. 5 depicts a method of computing a set of final free parameters in accordance with one embodiment of the present disclosure.

FIG. 6 depicts a method of deriving a total objective function in accordance with one embodiment of the present disclosure.

FIG. 7 depicts a method of deriving a set of initial free parameters in accordance with one embodiment of the present disclosure.

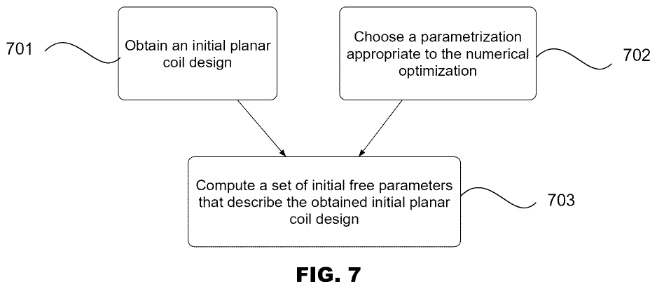

FIG. 8 illustrates an initial circular coil set (top and bottom) where the coils are evenly spaced out in the toroidal angle.

FIG. 9 illustrates an initial (top) and a final (bottom) planar coil design described by a set of initial and final free parameters. Three unique coils are optimized for a 2-field period stellarator symmetric QA equilibrium. The surface of the plasma is shaded to show the amplitude of the magnetic field error. These coils are the output of Example 2, herein.

FIG. 10 illustrates a set of three unique planar coil geometries that are yet to be rotated and translated into position (top) and a full 2 field period coil set after coils have been rotated and translated into position (bottom). Multiple copies of each coil are used to make a set since the equilibrium is stellarator symmetric. The magnetic field on the plasma boundary from the full coil set is also provided in the bottom image.

### DETAILED DESCRIPTION

### Definitions

It should also be understood that, unless clearly indicated to the contrary, in any methods claimed herein that include more than one step or act, the order of the steps or acts of the method is not necessarily limited to the order in which the steps or acts of the method are recited.

As used herein, the singular terms “a,” “an,” and “the” include plural referents unless context clearly indicates otherwise. Similarly, the word “or” is intended to include “and” unless the context clearly indicates otherwise. The term “includes” is defined inclusively, such that “includes A or B” means including A, B, or A and B.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of or “exactly one of,” or, when used in the claims, “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of,” “only one of” or “exactly one of.” “Consisting essentially of,” when used in the claims, shall have its ordinary meaning as used in the field of patent law.

The terms “comprising,” “including,” “having,” and the like are used interchangeably and have the same meaning. Similarly, “comprises,” “includes,” “has,” and the like are used interchangeably and have the same meaning. Specifically, each of the terms is defined consistent with the common United States patent law definition of “comprising” and is therefore interpreted to be an open term meaning “at least the following,” and is also interpreted not to exclude additional features, limitations, aspects, etc. Thus, for example, “a device having components a, b, and c” means that the device includes at least components a, b, and c. Similarly, the phrase: “a method involving steps a, b, and c” means that the method includes at least steps a, b, and c. Moreover, while the steps and processes may be outlined herein in a particular order, the skilled artisan will recognize that the ordering steps and processes may vary.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

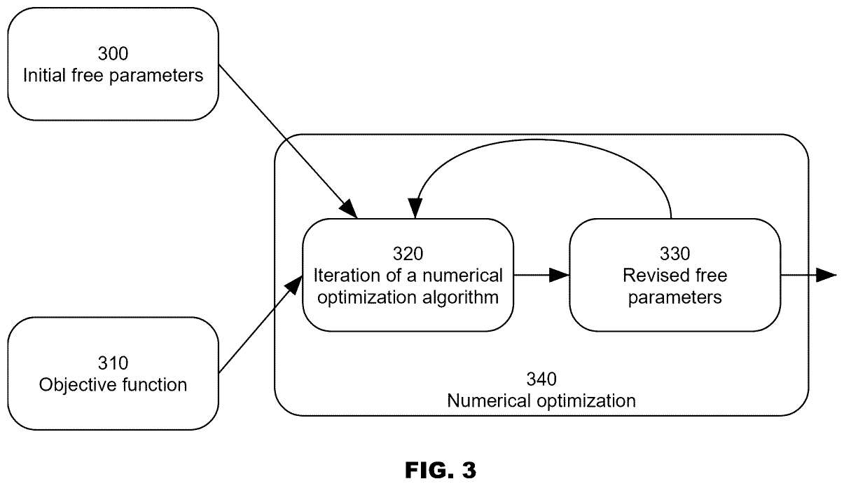

As used herein, the term “numerical optimization” refers to the use of any one of several algorithms which take in an initial set of free parameters and an objective function and output a revised one or more free parameters which are nearer to a local optimum of the objective function. For instance, and with reference to FIG. 3, numerical optimization may refer to the repeated application (“iteration”) of any one of several algorithms 320 which take in an initial one or more free parameters 300 and an objective function 310, and output a revised one or more free parameters 330 which are nearer to a local optimum of the objective function. Non-limiting examples of algorithms which can be used are the Quasi-Newton algorithm, the Levenberg-Marquardt algorithm, the Interior Point method, the Ellipsoid method, a Broyden-Fletcher-Goldfarb-Shanno algorithm, the Conjugate Gradient method, the Gradient Descent algorithm, and the L-BFGS-B algorithm. The free parameters are also commonly called optimization variables or degrees of freedom. The initial one or more free parameters is also commonly called an initial guess. The revised one or more free parameters is also commonly called the updated free parameters or an optimized free parameters. The objective function is also commonly called a figure of merit, a penalty function, a cost function, or a reward function.

As used herein, a “penalty function” is an objective function which describes a quantity, such that the free parameters which extremize the objective function have a satisfactory value of that undesired quantity. For example, if it is desired that some curves stay close to the origin, the penalty function may be the line integral of the spherical radius of the curve.

As used herein, a “total objective function” is a combination of multiple penalty functions, such that the extremum of the total objective function is one or more parameters which trades off undesired quantities. An example of the combination of multiple penalty functions is their linear addition, with some coefficient or “weight” which determines the relative importance of each undesired quantity. If the combination of penalty functions is not by simple linear addition, “weight” instead describes the relative importance of that penalty function to determining the value of the total objective function.

As used herein, an “iteration” is a single application of a numerical optimization algorithm. In some embodiments, a numerical optimization consists of one or more iterations, such as two or more iterations, such as three or more iterations, such as four or more iterations, such as six or more iterations, such as eight or more iterations, such as ten or more iterations, etc. For instance, an initial guess of iteration 1 is an initial one or more free parameters. The output of iteration 1 is the first revised free parameters. The initial guess of iteration N+1 is the Nth revised free parameters. The output of iteration N+1 is the N+1th revised free parameters. The output of a numerical optimization is the output of the last iteration.

As used herein, coils that are “described” by free parameters refers to the output of the inverse parametrizing function of the chosen parametrization. For example, if the parametrization is a Fourier representation, then the free parameters include Fourier amplitudes of Fourier modes. A design of coils that are “described” by those free parameters is obtained by performing an inverse Fourier transform of those modes, yielding a mean filament. The coil may be further specified by a cross section and an electrical current, more free parameters.

As used herein, a curve that is described as “planar” is a curve in which all points lie within one plane. The curve has no helicity, and no torsion as defined using the Frenet-Serret formulae.

As used herein, an electromagnetic coil that is described as “planar” is a coil whose electrical-current-carrying wires are collected around a mean filament, and whose mean filament is a planar curve as defined above.

As used herein, a curve which “encircles” a feature is one which interlocks or links the feature like the links of a chain.

As used herein, the phrases “planar encircling coil” or a “substantially planar encircling coil” refer to electromagnetic coils, such as for use in a stellarator, which encircle the plasma confined within the stellarator or within one or more components of the stellarator; and which is planar or substantially planar, respectively.

As used herein, a “parametrization” of an object is a method of specifying the properties of that object using one or more free parameters (numbers). One “parametrization” of a curve is to obtain the Cartesian X, Y, and Z coordinates of the points that make up the curve by performing an inverse Fourier transform on a list of Fourier amplitudes. The list of Fourier amplitudes is the list of free parameters of this parameterization. Another parametrization of a curve is to obtain the Cartesian X, Y, and Z coordinates of the points that make up the curve by using splines to interpolate between a list of spline knots. The list of spline knots is the list of free parameters of this parameterization. The parameterization of a coil may use one of these parametrizations of the mean filament of a coil, then use another set of parameters to describe the cross-section of the coil that is swept around this mean filament. For example, the cross section could be a rectangle described by a height dimension and a width dimension. In this case the free parameters that describe the mean filament, and the height and width of the cross section, together are the free parameters of this parametrization. The skilled artisan will appreciate that every parametrization entails a “parametrizing function,” which computes one or more free parameters from a description of the object to be parametrized; and an “inverse parametrizing function,” which computes a description of the object from one or more free parameters.

### Overview

The present disclosure is directed to systems methods for generating a set of final free parameters which describe a planar coil. In the systems and methods described herein, numerical optimization is used to produce a set of free parameters which describe a set of one or more electromagnetic coils which are advantageous for use in a stellarator. Compared to other coil optimization methods which use parametrizations which can only describe a limited set of planar coil shapes (ellipses, circles, D-shapes, rectangles), the parametrization used herein can describe many more kinds of shapes, permitting higher-performance and more engineering-feasible coils to be designed.

### System for Generating a Set of Final Free Parameters Describing Planar Coils

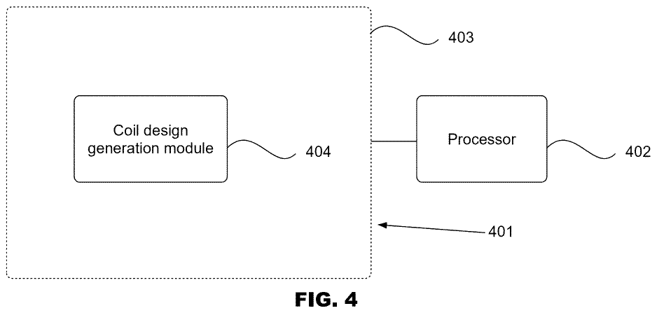

A system 401 for generating one or more substantially planar electromagnetic coils for use in a stellarator is illustrated in FIG. 4. In some embodiments, the system 401 includes one or more processors 402 and one or more memories 403 adapted to compute one or more free parameters using one or more of modules 404, where the computed one or more free parameters are used to generate a design for one or more coils for use in a stellarator. In some embodiments, a coil design generation module 404 computes one or more final free parameters based at least on (i) one or more initial free parameters; and (ii) a derived total objective function. The output of the coil design generation module 404 is the final free parameters which describe one or more planar coils.

### Method of Generating a Set of Final Free Parameters Describing Planar Coils

In some embodiments, the method of generating a set of final free parameters comprises numerically optimizing (506) a set of initial free parameters that describe a set of initial planar coils (505). The parametrization chosen to describe the planar coils may describe arbitrarily complex planar coil shapes. In some embodiments, the parametrization comprises two parts: (i) a parametrization of a planar coil which is represented as a closed curve in a 2D plane, and (ii) a parametrization for placing that 2D plane and therefore the coil into 3D space. In some embodiments, the parametrization of how to place a 2D plane into 3D space comprises a rotation matrix and translation vector. In some embodiments, the parametrization of how to place a 2D plane into 3D space comprises a 4×4 affine transformation, including rotation, translation, non-uniform scaling, and skew.

In some embodiments, the numerical optimization (506) is computed more than once, and where each computation is based on a different total objective function (504).

### Deriving a Total Objective Function

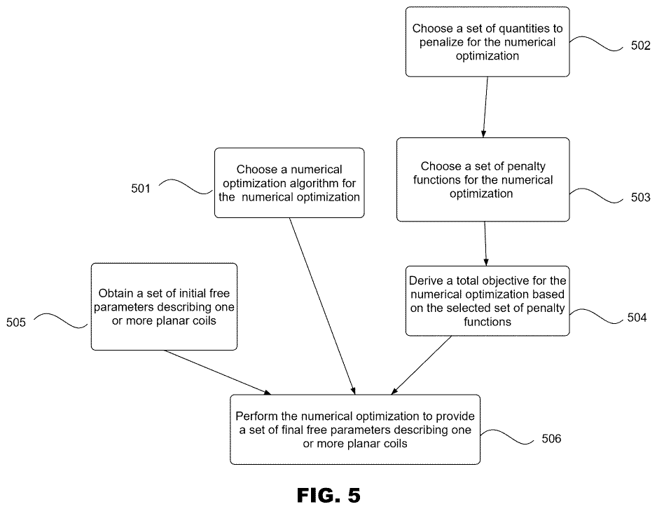

With reference to FIG. 5, a first step of the method includes deriving a total objective function (step 504). In some embodiments, the obtained total objective function is derived from one or more penalty functions. In some embodiments, the obtained total objective function is derived from two or more penalty functions. In some embodiments, the obtained total objective function is derived from three or more penalty functions.

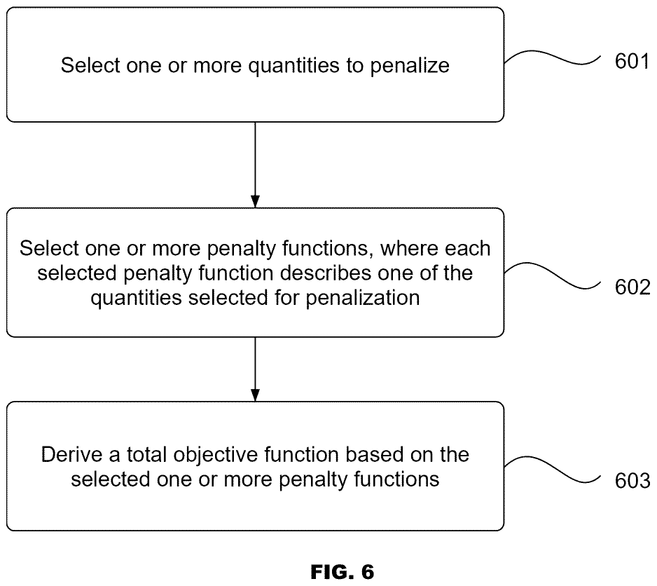

In some embodiments, and with reference to FIG. 6, a total objective function may be derived by (i) selecting one or more quantities to penalize (step 601); (ii) selecting one or more penalty functions, where each of the selected penalty functions describe one of the quantities selected for penalization (step 602); and (iii) deriving the total objective function based on the selected one or more penalty functions (step 603).

In some embodiments, one or more of the one or more quantities to penalize is selected from magnetic field error, coil-to-plasma distance, coil curvature (such as defined by the Frenet-Serret formulae), coil convexity, individual coil length, total coil length, total conductor length, and coil-to-coil spacing. In some embodiments, the one or more quantities to penalize is magnetic field error. In some embodiments, two or more quantities to penalize are selected, wherein a first of the two or more quantities to penalize is magnetic field error, and a second of the two or more quantities to penalize is selected from coil-plasma distance, coil curvature (such as defined by the Frenet-Serret formulae), coil convexity, individual coil length, total coil length, total conductor length, and coil-to-coil spacing.

In some embodiments, a magnetic field error is selected as a quantity to penalize such that the selected set of final free parameters describes one or more coils which produce the desired magnetic field, or a large portion of the desired magnetic field (greater than about 50% of the desired magnetic field, greater than about 90% of the desired magnetic field, or greater than about 99% of the desired magnetic field). In some embodiments, the desired magnetic field error of the coils described by the selected set of final free parameters is about 1%, such as about 0.5%, or such as about 0.1%. In some embodiments, if the coils described by the selected set of final free parameters act in combination with one or more additional magnet sets (such as ferritic inserts) to produce the desired magnetic field, the desired magnetic field error ranges from about 10% to about 50%.

In some embodiments, a coil-plasma distance is selected as a quantity to penalize such that the selected set of final free parameters describe one or more coils having sufficient spacing between the coils and a plasma surface, and such that space is provided to accommodate other components of a stellarator (e.g., a first wall, a neutronic breeding blanket, a neutronic shield, and structural members). In some embodiments, a desired coil-plasma distance is greater than about 50 cm, such as greater than about 100 cm, such as greater than about 20 cm, such as greater than about 150 cm, etc.

In some embodiments, a coil curvature is chosen as a quantity to penalize such that the selected set of final free parameters describe one or more coils which are not too curved to manufacture easily. Without wishing to be bound by any particular theory, it is believed that a tight curvature of electromagnetic coils introduces difficulties in manufacturing and winding electrical wire and introduces stress and magnetic field concentrations. In some embodiments, the desired curvature of a coil is less than about 10/m, such as less than about 5/m, such as less than about 2/m, such as less than about 1/m, such as less than about 0.5/m, such as less than about 0.2/m, such as less than about 0.1/m, etc.

In some embodiments, the coil-to-coil spacing is chosen as a quantity to penalize such that the selected set of final free parameters describe two or more coils which are sufficiently spaced apart from one another. In some embodiments, two or more coils must have some predetermined minimum space between them so that they do not physically interfere with each other. In some embodiments, the desired coil-to-coil spacing is greater than about 0.25 cm, such as greater than about 0.5 m, such as greater than about 1 m, etc.

As noted above, one or more penalty functions are selected, where each selected penalty function describes one of the quantities selected for penalization. For example, a first penalty function of the one or more penalty functions is selected which describes a first of the quantities selected for penalization; and a second penalty function of the two or more penalty functions describes a second of the two quantities selected for penalization.

In general, the penalty function selected includes one or more of a power-law of the quantity to be penalized, a thresholding of that quantity to be penalized using the Heaviside step function, a hyperbolic cosine of the quantity to be penalized, a spatial integral (a line integral, surface integral) of the quantity to be penalized, a maximum of the quantity to be penalized, and average of the quantity to be penalized.

In some embodiments, the one or more quantities to penalize and the corresponding one or more first penalty functions are selected from:

### Quantity: Coil-Coil Spacing

Example penalty function:

$$J = {\sum }_{i = 1}^{ncoils} {\sum }_{j = 1}^{i - 1} {d}_{i , j}$$

$${d}_{i , j} = {\int }_{{C}_{i}} {\int }_{{C}_{j}} {max ( 0 , {d}_{min} - {‖ {r}_{i} - {r}_{j} ‖}_{2} )}^{2} {dl}_{j} {dl}_{i}$$

Here, J is the penalty function, d_{i,j} is a summation of the distances between the mean filaments of coils i and j. dₘᵢₙ is the target minimum value supplied by the operator. rᵢ, rⱼ are position vectors of coils i and j and the integrals are taken over the curves Cᵢ, Cⱼ, the mean filaments of coils i and j.

In some embodiments, target values of d_{i,j} range from 1 mm⁴ to 5 m⁴. In other embodiments, target values of d_{i,j} range from 1 mm⁴ to 3 m⁴. In other embodiments, target values of d_{i,j} range from 1 cm⁴ to 1 m⁴. In other embodiments, target values of d_{i,j} range from 10 cm⁴ to 1 m⁴.

### Quantity: Plasma-Coil Spacing

Example penalty function:

$$J = {\sum }_{i = 1}^{ncoils} {d}_{i}$$

$${d}_{i} = {\int }_{{C}_{i}} {\int }_{S} {max ( 0 , {d}_{min} - {‖ {r}_{i} - s ‖}_{2} )}^{2} {dl}_{i} ds$$

Here, J is the penalty function, dᵢ is a summation of the distances between points on coil i to the plasma surface, s. rᵢ, s are the position vectors of coil i and the plasma surface, respectively. The integrals are taken over curve i and the plasma surface.

In some embodiments, target values of dᵢ range from 1 mm⁴ to 10 m⁴. In other embodiments, target values of dᵢ range from 1 cm⁴ to 5 m⁴. In other embodiments, target values of dᵢ range from 1 cm⁴ to 3 m⁴. In other embodiments, target value of dᵢ range from 10 cm⁴ to 1 m⁴.

### Quantity: Coil Curvature

Example penalty function: J=∫_{curve} H(κ_{*})(κ_{*})^{p}dl

$$κ = \frac{\vert {r}^{′} \times {r}^{″} \vert}{{\vert {r}^{′} \vert}^{3}}$$

Serret formulae, κ_{*}=κ−κ₀. Here, κ₀ and p (where p>1) are input parameters, and H(x) is the Heaviside step function. κ is the curvature at a given point along the curve.

In some embodiments, target values of κ₀ range from 0 m⁻¹ to 10 m⁻¹. In other embodiments, target values of κ₀ range from 0 m⁻¹ to 5 m⁻¹. In other embodiments, target values of κ₀ range from 0 m⁻¹ to 3 m⁻¹.

### Quantity: Coil Convexity (Option 1)

Example penalty function: J=∫_{curve} H(κ_{*})(κ_{*})^{p} dl,
where J is the penalty function, κ is the curvature as defined using the Frenet-Serret formulae, κ_{*}=κ₀−κ. Here, κ₀ and p (where p>1) are input parameters, and H(x) is the Heaviside step function. The curve is convex if the curve starts convex and the curvature never goes to zero.

In some embodiments, target values of κ₀ range from 0 m⁻¹ to. 1 m⁻¹. In other embodiments, target values of κ₀ range from 0 m⁻¹ to 1 m⁻¹. In other embodiments, target values of κ₀ range from 0 m⁻¹ to 10 m⁻¹.

### Quantity: Coil Convexity (Option 2)

Example penalty function: J=∫_{curve} κdl−2π,
where J is the penalty function, K is the curvature as defined using the Frenet-Serret formulae. The curve is convex if and only if J is zero.

### Quantity: Individual Coil Length

Example penalty function: J=(∫_{curve} dl−L₀)²,
where J is the penalty function and L₀ is the target coil length. This objective simply integrates the arclength of the curve to determine the coil's total length and calculates the difference between the coils length and the target length.

In some embodiments, individual coil length targets could be applied to some or all of the coils under consideration. In those embodiments where individual coil lengths for multiple coils are considered, the target values for a given coil can be less than, equal to, or greater than the target values for any of the other coils. For example, one coil can have a length target of 12 m where another coil has a length target of 14 m.

In some embodiments, target values of J range from between about 1 m to about 100 m. In other embodiments, target values of J range from between about 2 m to about 50 m. In other embodiments, target values of J range from between about 4 m to about 20 m. In other embodiments, target values of J range from between about 6 m to about 15 m.

### Quantity: Total Coil Length

Example penalty function: J=Σᵢ∫_{curve} dlᵢ,
where J is the penalty function.

This objective sums over the integral along each curve to target the total length of all coils.

In some embodiments, target values of J range from between about 1 m to about 100,000 m. In other embodiments, target values of J range from between about 10 m to about 10,000 m. In other embodiments, target values of J range from between about 10 m to about 1,000 m. In other embodiments, target values of J range from between about 10 m to about 100 m. In other embodiments, target values of J range from between about 10 m to about 50 m.

### Quantity: Total Conductor Length

Example penalty function: J=Σᵢ|Iᵢ|∫_{curve} dlᵢ,
where J is the penalty function.

This objective sums over the coil lengths times the coil currents for the total conductor usage of the magnets.

In some embodiments, target values of J range from between about 1×10⁴ Am to about 1×10¹⁰ Am. In other embodiments, target values of J range from between about 1×10⁵ Am to about 1×10¹⁰ Am. In other embodiments, target values of J range from between about 1×10⁶ Am to about 1×10¹⁰ Am. In other embodiments, target values of J range from between about 1×10⁷ Am to about 1×10¹⁰ Am. In other embodiments, target values of J range from between about 1×10⁸ Am to about 1×10¹⁰ Am. In other embodiments, target values of J range from between about 1×10⁹ Am to about 1×10¹⁰ Am.

### Quantity: Magnetic Field Error

Example penalty function:

$$J = {\int }_{S} {H}_{U} ( \vert B \cdot \hat{n} - {T}_{Bn} \vert ) {( \vert B \cdot \hat{n} - {T}_{Bn} \vert - U )}^{2} dS$$

where J is the penalty function, the surface integral is taken over the plasma surface S, B is the magnetic field, \hat{n} is the surface-normal vector of the plasma surface, T_{Bn} is the target normal magnetic field on the plasma surface, H is a Heaviside function and U is the maximum allowable field error.

In some embodiments, target values of/are about 0.5 T² m². In other embodiments, target values of J are about 0.15 T² m². In other embodiments, target values of J are 0.05 T² m². In other embodiments, target values of/are about 0.015 T² m².

In some embodiments, the one or more penalty functions depend upon one or more additional coils included within a stellarator. For instance, and in some embodiments, the selected set of final free parameters describe one or more coils which may operate alongside one or more additional sets of electromagnetic coils, such as non-planar coils (120) or planar non-encircling coils (140) or planar field-shaping coils (220). In some embodiments, the measures of feasibility comprises a total amount of conductor or maximum local magnetic field required in the one or more additional coils to reduce the magnetic field error to substantially zero (e.g., about 0.01 Tesla).

Following the selection of the one or more penalty functions (e.g., two or more, three or more, etc.), a total objective function is derived (step 504) by combining the two or more selected penalty functions. In some embodiments, the total objective function is the linear sum of the penalty functions with different weights as defined in Formula I:

$${f}_{total} ( \vec{x} ) = {\sum }_{i} {w}_{i} {f}_{i} ( \vec{x} ) , \qquad ( Formula I )$$

where the functions fᵢ are individual penalty functions which describe an undesired property of a design of one or more coils, and where the weights wᵢ control the importance of fᵢ relative to other penalty functions comprising the total objective function fₜₒₜₐₗ. For instance, if a penalty function which describes one quantity, such as magnetic field error, is combined with a penalty function which describes another quantity, such as coil curvature, the resultant optimum of this total objective function is a tradeoff between the two quantities.

In some embodiments, each penalty function (including each penalty function combined into the total objective function) has a weight wᵢ. In these embodiments, the selection of weights determines the relative importance of that penalty function in generating each of the sets of candidate final free parameters, described below. For example, if the weight of a penalty function describing magnetic field error is about 1000, and the weight of a penalty function describing coil curvature is about 1, a generated set of candidate final free parameters will describe one or more coils which faithfully reproduces the desired magnetic field but has undesirable, high curvature. The weights and penalty functions can be different for different steps in the method of the present disclosure.

### Selection of a Numerical Optimization Algorithm

With reference again to FIG. 5, following the obtaining of a total objective function, a numerical optimization algorithm is selected (step 502). In some embodiments, the numerical optimization algorithm is a Quasi-Newton algorithm. In other embodiments, the numerical optimization algorithm is a Levenberg-Marquardt algorithm. In other embodiments, the numerical optimization algorithm is an Interior Point method. In other embodiments, the numerical optimization algorithm is an Ellipsoid method. In other embodiments, the numerical optimization algorithm is a Broyden-Fletcher-Goldfarb-Shanno algorithm. In other embodiments, the numerical optimization algorithm is a Conjugate Gradient method. In other embodiments, the numerical optimization algorithm a Gradient Descent algorithm. In other embodiments, the numerical optimization algorithm is L-BFGS-B, which is a variation of the Broyden-Fletcher-Goldfar-Shanno algorithm.

In some embodiments, the selection of the numerical optimization algorithm (step 502) is informed based on the derived total objective function (see step 504) and a parametrization. For example, some algorithms are known to be superior when there are a large number of free parameters (greater than 1000), such as stochastic gradient descent. By way of another example, some algorithms are known to be superior when the total objective function is smooth, such as the Quasi-Newton method. By way of yet a further example, some algorithms are known to be superior when the total objective function is convex, like the Interior Point method.

### Computation of a Set of Initial Free Parameters

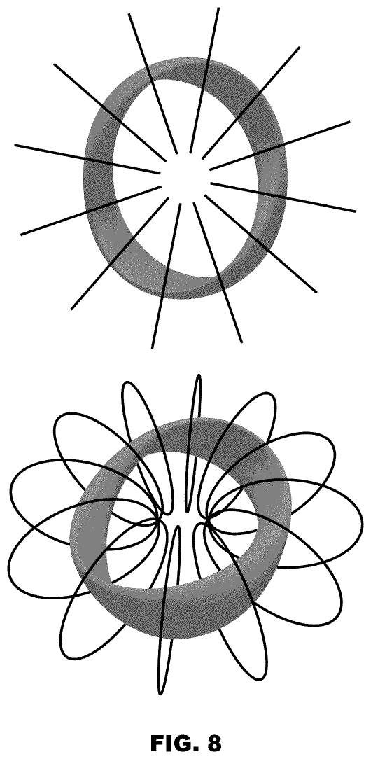

With reference to FIG. 8, an initial planar coil design is obtained, describing one or more planar coils (step 701). In some embodiments, the initial planar free coil design describes a set of rotationally symmetric, circular coils. In some embodiments, the initial planar coil design describes a set of coils which are placed and rotated rotationally symmetrically around a common axis. In some embodiments, the initial planar coil design describes a set of coils which are equally spaced around and link an axis within the plasma. FIG. 8 illustrates a top-down view of an initial planar coil design composed of 12 circular coils that are equally spaced in the toroidal angle (top). FIG. 8 also illustrates a perspective view of the same initial coil design (bottom). An example plasma boundary is plotted with the initial planar coil design.

In embodiments where the initial planar coil design describes a set of circular coils that are placed and rotated rotationally symmetrically about a common axis, the skilled artisan would appreciate that the center of each coil should be about where the major radius of the plasma torus is, and the coil radius should be larger than the plasma minor radius. In some embodiments, the choice of coil minor radius is toroidally dependent (not rotationally symmetrical) because the major/minor radius of the plasma may vary significantly as one moves in the toroidal direction.

In some embodiments, the choice of a rotationally symmetric initial planar coil design necessarily entails a choice of an initial radius of the coils and a radial distance from the origin of a coordinate system to a coil center. The initial coil radii may be chosen such that the coils do not come close to intersecting each other and are everywhere outside of the plasma.

In some embodiments, the toroidal magnetic flux is a fixed constraint from the plasma that determines the sum of the electrical current carried by all the planar encircling coils, also referred to as the linking current. The toroidal magnetic flux constrains the sum of the encircling coil currents initially and all throughout an optimization. This is a linear constraint on the free parameters and can be applied with Lagrange multipliers.

In some embodiments, the desired number of initial planar coils ranges from between about about 2 coils to about 100 coils. In other embodiments, the desired number of coils ranges from between about 2 coils to about 50 coils. In yet other embodiments, the desired number of coils ranges from between about 2 coils to about 20 coils. In further embodiments, the desired number of coils ranges from between about 2 coils to about 16 coils. In further embodiments, the desired number of coils ranges from between about 2 coils to about 12 coils.

In some embodiments, the initial radius of the coils of the initial planar coil design ranges from between about 1 cm to about 2000 cm. In other embodiments, the initial radius of the coils ranges from between about 1 cm to about 400 cm. In yet other embodiments, the initial radius of the coils ranges from between about 50 cm to about 300 cm. In yet other embodiments, the initial radius of the coils ranges from between about 60 cm to about 200 cm.

In some embodiments, the initial radial distance of each coil of the initial planar coil design ranges from about 1 m to about 15 m. In other embodiments, the radial distance ranges from about 1 m to about 11 m. In yet other embodiments, the radial distance ranges from about 1.5 m to about 8.0 m. In yet other embodiments, the radial distance ranges from about 2.0 m to about 5.0 m.

After the initial planar coil design is obtained (step 701), a parametrization appropriate for a preliminary planar optimization is chosen (step 702). Next, a set of initial free parameters are computed by fitting the chosen parameterization to the shape of the obtained initial coil. These initial free parameters are computed to describe the obtained initial planar coil design with the chosen parameterization.

### EXAMPLES

Described below are certain non-limiting methods of generating a coil array, such as a coil array for a stellarator, such as planar encircling coils for a stellarator.

### Example 1

In some embodiments, the implementation of the methods of the present disclosure utilizes a truncated Fourier series to represent the shape of curves in the numerical optimization process, a parametrization of a Fourier representation. For example, in a Cartesian coordinate system, a planar coil can be parameterized with a Fourier series in the x-coordinate and y-coordinate:

$$x ( ζ ) = {\sum }_{n = 1}^{{N}_{F}} {x}_{c , n} cos ( n ζ ) + {\sum }_{n = 1}^{{N}_{F}} {x}_{s , n} sin ( n ζ ) \qquad ( Formula II )$$

$$y ( ζ ) = {\sum }_{n = 1}^{{N}_{F}} {y}_{c , n} cos ( n ζ ) + {\sum }_{n = 1}^{{N}_{F}} {y}_{s , n} sin ( n ζ ) \qquad ( Formula II )$$

where x_{c,n}, x_{s,n}, y_{c,n}, and y_{s,n} are a subset of the free parameters: cosine and sine amplitudes of order n, respectively, and zeta parameterizes the distance along the curve. These amplitudes, which control the shape of the curve, are a subset of the free parameters in the coil numerical optimization (with coil currents, rotations of the curve and translation of the curve being the other free parameters). Another example, in a polar coordinate system, a planar can be parameterized with a Fourier series for the radius,

$$r ( θ ) = {\sum }_{n = 1}^{{N}_{F}} {r}_{c , n} cos ( n θ ) + {\sum }_{n = 1}^{{N}_{F}} {r}_{s , n} sin ( n θ ) \qquad ( Formula III )$$

where r_{c,n} and r_{s,n} are some of the free parameters: cosine and sine amplitudes of order n, respectively, and the polar angle theta parameterizes the distance along the curve.

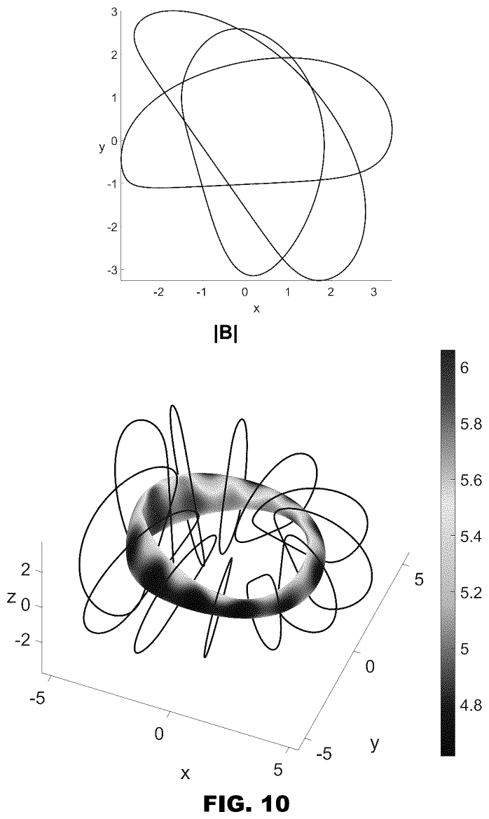

Formula II is used to parameterize the shape of one of the coils in FIG. 10 with N_{F}=4.

$$x ( ζ ) = 2.46020084397 \; 7021 cos ( ζ ) + . 265097464343 \; 2817 cos ( 2 ζ ) - \text{.0003466455656879121} cos ( 3 ζ ) - . 00019403038 \; 28093831 cos ( 4 ζ ) - \text{.584496367326769} sin ( ζ ) + . 475716103590 \; 2669 sin ( 2 ζ ) + \text{.1389762228825524} sin ( 3 ζ ) + . 00495969094616 \; 8259 sin ( 4 ζ )$$

$$y ( ζ ) = - 1.828838 \; 797671311 cos ( ζ ) - \text{.3535182177521406} cos ( 2 ζ ) - . 106527049239 \; 2010 cos ( 3 ζ ) + \text{.002827846262181478} cos ( 4 ζ ) + 2.49365389320 \; 0756 sin ( ζ ) + \text{.2994971218983418} sin ( 2 ζ ) - . 06537972 \; 622479631 sin ( 3 ζ ) - \text{.001893128148821967} sin ( 4 ζ )$$

This shape is translated and rotated multiple times to make different coils in this design.

### Example 2—Coil Numerical Optimization Method I

This example provides an exemplary method of generating a set of final free parameters that describe a set of planar electromagnetic coils for confining a plasma within a stellarator. This set of coils contains 12 coils, though 9 of them are duplicates, leaving only 3 unique coils. Several penalty functions are included, notably the penalty function for the magnetic field error.

### Coil Numerical Optimization I

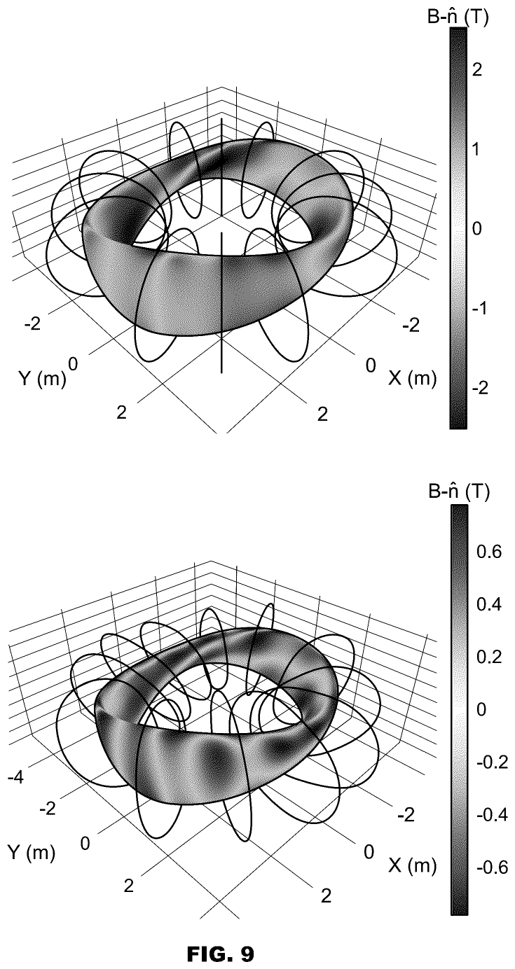

The initial circular coil set is given in the top image of FIG. 9 along with the normal magnetic field error on an example plasma boundary. The initial coils are parameterized with Formula III using only n=0,1 modes initially. The coils are initialized with 7.5 MA of current to generate an average field of approximately 5 T within the plasma volume. Coil currents are held fixed during the optimization.

A maximum normal field error constraint of 0.75 T is applied to the optimization along with a list of engineering constraints. The initial circular coils set violates this maximum normal field error constraint. The field error objective is initialized with a weighting of 10. The coil to plasma surface distance is constrained to a value of 75 cm with a weighting of 1. A constraint on the minimum coil-to-coil distance is set to 50 cm and initialized with a weight of 10. The coils are kept convex with a constraint on the minimum curvature of 0.05 m⁻¹ with a weighting of 10,000. The coils also have a maximum constraint on their curvature of 0.05 m⁻¹ with a weighting of 10,000.

A numerical optimization is performed using a maximum Fourier resolution of 2, N_{F}=2 and allowing all the Fourier modes to vary. The numerical optimization's output is provided with the sum of weighted objectives given in the third column.

| | Objective | Total | Objective | | Gradient |
|---|---|---|---|---|---|
| Iteration | Evaluations | Objective | Decrease | Step Size | Magnitude |
| 0 | 1 | 1.388e+03 | | | 5.136e+03 |
| 1 | 3 | 5.931e+02 | 7.948e+02 | 1.986e−01 | 2.770e+03 |
| 2 | 5 | 2.385e+02 | 3.546e+02 | 8.580e−01 | 2.912e+03 |
| 3 | 6 | 2.180e+01 | 2.167e+02 | 3.139e−01 | 5.422e+02 |
| 4 | 9 | 1.472e+01 | 7.078e+00 | 3.372e−02 | 2.813e+02 |
| 5 | 10 | 8.234e+00 | 6.490e+00 | 5.382e−02 | 1.297e+02 |
| 6 | 12 | 6.275e+00 | 1.959e+00 | 2.684e−02 | 1.080e+02 |
| 7 | 17 | 6.266e+00 | 8.809e−03 | 2.217e−04 | 2.145e+02 |
| 8 | 18 | 6.254e+00 | 1.220e−02 | 2.155e−04 | 2.078e+02 |
| 9 | 19 | 6.230e+00 | 2.428e−02 | 4.302e−04 | 1.950e+02 |
| 10 | 20 | 6.182e+00 | 4.810e−02 | 8.571e−04 | 1.720e+02 |
| 11 | 21 | 6.087e+00 | 9.450e−02 | 1.702e−03 | 1.348e+02 |
| 12 | 22 | 5.905e+00 | 1.828e−01 | 3.353e−03 | 1.033e+02 |
| 13 | 23 | 5.560e+00 | 3.446e−01 | 6.530e−03 | 9.888e+01 |
| 14 | 24 | 4.937e+00 | 6.226e−01 | 1.270e−02 | 9.087e+01 |
| 15 | 25 | 3.884e+00 | 1.054e+00 | 2.516e−02 | 7.634e+01 |
| 16 | 27 | 3.432e+00 | 4.521e−01 | 1.244e−02 | 6.966e+01 |
| 17 | 28 | 2.653e+00 | 7.785e−01 | 2.510e−02 | 5.766e+01 |
| 18 | 31 | 2.566e+00 | 8.728e−02 | 3.106e−03 | 5.631e+01 |
| 19 | 33 | 2.523e+00 | 4.283e−02 | 1.552e−03 | 5.564e+01 |
| 20 | 35 | 2.502e+00 | 2.122e−02 | 7.759e−04 | 5.530e+01 |
| 21 | 36 | 2.460e+00 | 4.203e−02 | 1.553e−03 | 5.462e+01 |
| 22 | 40 | 2.458e+00 | 1.305e−03 | 4.849e−05 | 5.460e+01 |
| 23 | 41 | 2.458e+00 | 1.694e−04 | 9.698e−05 | 1.274e+02 |
| 24 | 42 | 2.458e+00 | 5.625e−04 | 1.726e−05 | 1.259e+02 |
| 25 | 43 | 2.456e+00 | 1.123e−03 | 3.459e−05 | 1.23le+02 |
| 26 | 44 | 2.454e+00 | 2.238e−03 | 6.942e−05 | 1.176e+02 |
| 27 | 45 | 2.450e+00 | 4.448e−03 | 1.397e−04 | 1.075e+02 |
| 28 | 46 | 2.441e+00 | 8.800e−03 | 2.821e−04 | 9.000e+01 |
| 29 | 47 | 2.424e+00 | 1.731e−02 | 5.707e−04 | 6.390e+01 |
| 30 | 48 | 2.390e+00 | 3.387e−02 | 1.151e−03 | 5.329e+01 |
| 31 | 49 | 2.324e+00 | 6.591e−02 | 2.305e−03 | 5.205e+01 |
| 32 | 50 | 2.198e+00 | 1.263e−01 | 4.573e−03 | 4.963e+01 |
| 33 | 51 | 1.965e+00 | 2.322e−01 | 8.946e−03 | 4.499e+01 |
| 34 | 52 | 1.569e+00 | 3.966e−01 | 1.737e−02 | 3.684e+01 |
| 35 | 53 | 9.891e−01 | 5.797e−01 | 3.425e−02 | 2.439e+01 |
| 36 | 54 | 3.748e−01 | 6.143e−01 | 6.625e−02 | 1.054e+01 |
| 37 | 57 | 3.228e−01 | 5.204e−02 | 8.758e−03 | 8.944e+00 |
| 38 | 58 | 2.393e−01 | 8.343e−02 | 1.703e−02 | 6.813e+00 |
| 39 | 61 | 2.304e−01 | 8.936e−03 | 2.261e−03 | 6.574e+00 |
| 40 | 62 | 2.134e−01 | 1.697e−02 | 4.467e−03 | 6.107e+00 |
| 41 | 66 | 2.129e−01 | 5.113e−04 | 1.425e−04 | 6.093e+00 |
| 42 | 68 | 2.128e−01 | 1.519e−04 | 7.129e−05 | 2.422e+01 |
| 43 | 69 | 2.125e−01 | 2.730e−04 | 5.832e−05 | 1.758e+01 |
| 44 | 70 | 2.120e−01 | 5.123e−04 | 1.224e−04 | 9.665e+00 |
| 45 | 71 | 2.110e−01 | 9.833e−04 | 2.500e−04 | 6.031e+00 |
| 46 | 72 | 2.091e−01 | 1.934e−03 | 5.015e−04 | 5.968e+00 |
| 47 | 73 | 2.052e−01 | 3.812e−03 | 9.999e−04 | 5.846e+00 |
| 48 | 74 | 1.978e−01 | 7.417e−03 | 1.976e−03 | 5.607e+00 |
| 49 | 75 | 1.837e−01 | 1.410e−02 | 3.881e−03 | 5.252e+00 |
| 50 | 76 | 1.578e−01 | 2.597e−02 | 7.831e−03 | 4.679e+00 |
| 51 | 77 | 1.493e−01 | 8.462e−03 | 1.520e−02 | 1.119e+01 |
| 52 | 78 | 1.184e−01 | 3.088e−02 | 9.353e−03 | 3.411e+00 |
| 53 | 79 | 1.008e−01 | 1.764e−02 | 8.754e−03 | 2.886e+00 |
| 54 | 80 | 7.830e−02 | 2.248e−02 | 1.144e−02 | 2.246e+00 |
| 55 | 81 | 5.083e−02 | 2.747e−02 | 2.218e−02 | 1.554e+00 |
| 56 | 82 | 2.113e−02 | 2.970e−02 | 4.959e−02 | 9.770e−01 |
| 57 | 83 | 3.967e−03 | 1.716e−02 | 8.561e−02 | 6.165e−01 |
| 58 | 85 | 7.650e−04 | 3.202e−03 | 3.870e−02 | 1.108e−01 |
| 59 | 88 | 5.150e−04 | 2.500e−04 | 1.059e−02 | 7.304e−02 |
| 60 | 90 | 4.210e−04 | 9.402e−05 | 4.503e−03 | 6.121e−02 |
| 61 | 92 | 3.807e−04 | 4.037e−05 | 2.043e−03 | 5.824e−02 |
| 62 | 94 | 3.614e−04 | 1.922e−05 | 1.003e−03 | 5.737e−02 |
| 63 | 95 | 3.272e−04 | 3.426e−05 | 1.521e−03 | 5.589e−02 |
| 64 | 96 | 2.663e−04 | 6.083e−05 | 3.049e−03 | 5.241e−02 |
| 65 | 97 | 1.702e−04 | 9.616e−05 | 6.276e−03 | 4.354e−02 |
| 66 | 98 | 5.571e−05 | 1.145e−04 | 1.292e−02 | 2.539e−02 |
| 67 | 99 | 9.024e−08 | 5.562e−05 | 1.963e−02 | 6.157e−03 |
| 68 | 101 | 6.167e−09 | 8.407e−08 | 6.809e−05 | 5.008e−04 |
| 69 | 102 | 0.000e+00 | 6.167e−09 | 6.758e−05 | 0.000e+00 |

A summary of the results is provided in the table below.

| | Numerical | Numerical | |
|---|---|---|---|
| | optimization | optimization | |
| Constraint | Target | Results | |
| Maximum curvature | κ₀ = 1 m⁻¹ | .815 | m⁻¹ |
| Minimum coil-to-surface distance | dₘᵢₙ = 75 cm | 75.6 | cm |
| Minimum coil-to-coil distance | dₘᵢₙ = 50 cm | 66.9 | cm |
| Convexity (option I) | κ₀ = .05 m⁻¹ | .050 | m⁻¹ |
| Maximum Field error | U = .75 T | .75 | T |

The optimization managed to satisfy all the user requested constraints hence why the final cost value is converging to 0. The final coil set is provided at the bottom of FIG. 9 along with the normal magnetic field on the plasma boundary.

### ADDITIONAL EMBODIMENTS

In some embodiments, the optimizations are run with a small number of iterations and with targets and/or weights that may not be the final desired values. a small number of iterations (e.g., about 10 iterations, about 20 iterations, about 50 iterations, etc.), the targets and/or weights can be adjusted based on the outcome of the optimization. In some embodiments, the targets and/or weights can successively be pushed to values closer to the final desired values. In some embodiments, this process of adjusting targets and/or weights after a small number of iterations can be repeated with targets that are progressively closer to a desired final value, with weights that become larger to more strongly penalize large deviations from the target. In some embodiments, this process of adjusting targets and/or weights after a small number of iterations can be repeated with targets that are progressively closer to a desired final value, with weights that become larger to more strongly penalize large deviations from the target. For example, the operator might want a final minimum coil-coil spacing of 40 cm. They might start the optimization using a coil-coil penalty function with 20 cm target minimum spacing (along with other potential penalty functions). The optimization is then run for 10 (or other number) iterations. The operator then increases the target to 30 cm minimum coil-coil spacing and reruns the optimization for 10 (or other number) iterations. This process continues until resulting coil-coil spacing meets some value desired by the operator.

In some embodiments, for any of the described numerical optimizations, the operator may specify the maximum number of iterations that the optimization algorithm will perform before ending the optimization. The larger the number of iterations, the closer the optimization will be to being “stuck” in a (potentially undesirable) local minimum. By choosing a smaller number of iterations, the result of the optimization may target a subset of local minima (relative to the larger number of possible local minima before the optimization), but the solution space will not be reduced to a single local minimum. This, it is believed, affords some freedom to vary the total objective function at different stages in the optimization to target different plasma and coil properties at different points. In some embodiments, the maximum number of iterations ranges from between 5 to about 200. In other embodiments, the maximum number of iterations ranges from between 10 to about 50. In yet other embodiments, the maximum number of iterations ranges from between 10 to about 20.

In a second additional embodiment, disclosure provides a method of generating a planar coil array comprising obtaining an initial coil array; computing a preliminary optimized coil array that is optimized for coil shape, coil position, and coil current. In some embodiments, the computing of the preliminary optimized coil array comprises: (i) defining one or more input parameters; (ii) initializing a coil array design based on the defined one or more input parameters; (iii) receiving one or more user defined parameters; and (iv) performing a first optimization on the obtained initial coil array based on the received one or more user defined parameters and one or more engineering constraints to provide the preliminary optimized coil array.

In some embodiments, the one or more defined input parameters are selected from the group consisting of a desired number of coils in the planar coil array, a parameterization, an initial radius of coils, and a radial distance from the origin of a coordinate system to a coil center. In some embodiments, the desired number of coils in the planar coil array ranges from between about 2 coils to about 100 coils. In some embodiments, the desired number of coils in the planar coil array ranges from between about 2 coils to about 50 coils. In some embodiments, the maximum order of the Fourier series ranges from between about 1 to about 20. In some embodiments, the initial radius of the coils ranges from between about 1 to about 2000 cm. In some embodiments, the radial distance ranges from about 1 m to about 15 m. In some embodiments, the coil design is initialized to be (i) circular or substantially circular, (ii) equally or substantially equally spaced in the toroidal direction; (iii) have their centers at the prescribed radial distance from the origin, and (iv) have the desired radius. In some embodiments, the one or more user defined parameters comprise the degrees of freedom for the coil parameterization in use. In some embodiments, the one or more user defined parameters comprise one or more optimization algorithms. In some embodiments, the one or more user defined parameters comprise one or more objective and/or penalty functions.

1. A method of generating a set of final free parameters which describe a design of one or more electromagnetic coils that are planar, comprising:
(a) obtaining a set of initial free parameters, where the set of initial free parameters describe one or more planar coils; and
(b) obtaining a total objective function, wherein the total objective function is derived from at least one penalty function, wherein one of the at least one penalty function is a magnetic field penalty function, and wherein the magnetic field penalty function has an initial weight.

2. The method of claim 1, wherein the total objective function is derived from at least two penalty functions.

3. The method of claim 2, wherein the at least two penalty functions each correspond to a different quantity to penalize.

4. The method of claim 3, wherein a second of the at least two penalty functions is a magnetic field error quantity to penalize.

5. The method of claim 3, wherein the different quantities to penalize are selected from the group consisting of magnetic field error, coil-to-plasma distance, coil curvature, coil convexity, individual coil length, total coil length, total conductor length, and coil-to-coil spacing.

6. The method of claim 1, wherein the set of initial free parameters are derived by performing a preliminary numerical optimization based on a set of initial free parameters and a total objective function for the preliminary numerical optimization.

7. The method of claim 6, wherein the total objective function for the preliminary numerical optimization is derived from two or more penalty functions for the preliminary numerical optimization.

8. The method of claim 6, wherein the set of initial free parameters are derived by: (i) obtaining an initial planar coil design; (ii) choosing a parametrization appropriate for the preliminary planar optimization; and (iii) parametrizing the preliminary planar coil design with the chosen parametrization.

9. The method of claim 8, wherein the initial planar coil design describes a set of rotationally symmetric, circular coils.

10. The method of claim 8, wherein the preliminary planar design describes a set of coils which are placed and rotated rotationally symmetrically around a common axis.

11. The method of claim 8, wherein the initial planar coil design includes between about 2 and about 100 coils.

12. The method of claim 8, wherein the preliminary planar coil design includes one or more coils each having an initial radius ranging from between about 1 cm to about 2000 cm.

13. The method of claim 1, wherein the predetermined numerical optimization is selected from the group consisting of a Quasi-Newton algorithm, a Levenberg-Marquardt algorithm, an Interior Point method, an Ellipsoid method, a Broyden-Fletcher-Goldfarb-Shanno algorithm, a Conjugate Gradient method, a Gradient Descent algorithm, and an L-BFGS-B algorithm.

14. A method of generating a set of final free parameters which describe a design of one or more electromagnetic coils that are planar, comprising:
(a) obtaining a field-shaping coil system comprising a plurality of planar shaping coils, wherein the field-shaping coil system is adapted to magnetically confine a plasma;
(b) generating a set of final free parameters which describe the design of the one or more electromagnetic coils that are planar, where the one or more electromagnetic coils that are planar encircle and interlock the field-shaping coil system, wherein the set of final free parameters are generated by obtaining a total objective function, wherein the total objective function is derived from at least one penalty function, wherein the at least one penalty function is derived from at least one quantity to penalize, wherein the at least one quantity to penalize is selected from the group consisting of a required current in the plurality of shaping coils, a required conductor length of the plurality of shaping coils, and a maximum magnetic field of the plurality of shaping coils.

15. The method of claim 14, wherein the field-shaping coil system comprises one or more field shaping units which define a void adapted to confine the plasma, wherein each field shaping unit comprises: (i) one or more structural mounting elements; and (ii) the plurality of shaping coils disposed on a surface of the one or more structural mounting elements, wherein the plurality of shaping coils do not interlock with each other, and where each shaping coil of the plurality of shaping coils do not individually encircle the plasma.

16. The method of claim 15, wherein each of the one or more field shaping units comprises between about 5 and about 100 shaping coils.

17. The method of claim 14, wherein the plurality of shaping coils is comprised of a superconducting material.
